(19) United States
(12) Patent Application Publication
(10) Pub. No.: US 2017/0278589 A1
(43) Pub. Date: Sep. 28, 2017

(54) METAL OXIDE PARTICLES FOR BONDING, SINTERING BINDER INCLUDING SAME, PROCESS FOR PRODUCING METAL OXIDE PARTICLES FOR BONDING, AND METHOD FOR BONDING ELECTRONIC COMPONENTS

(71) Applicant: HITACHI, LTD., Tokyo (JP)

(72) Inventors: Yusuke YASUDA, Tokyo (JP); Toshiaki MORITA, Tokyo (JP); Yoshio KOBAYASHI, Hitachi (JP); Takafumi MAEDA, Hitachi (JP)

(73) Assignee: HITACHI, LTD., Tokyo (JP)

(21) Appl. No.: 15/510,865

(22) PCT Filed: Nov. 18, 2015
(86) PCT No.: PCT/JP2015/082333

§ 371 Date: Mar. 13, 2017

(30) Foreign Application Priority Data
Dec. 3, 2014 (JP) 2014-244707

(51) Int. Cl. H01B 1/22; H01R 4/02; B82Y 30/00; C01G 3/02; H01L 21/52

(52) U.S. Cl. CPC H01B 1/22; C01G 3/02; H01L 21/52; B82Y 30/00; H01R 4/02

(57) ABSTRACT

Provided are: a sintering binder including nanoparticles, a method for producing the sintering binder, and a method for bonding using the sintering binder. The sintering binder mainly includes cuprous oxide nanoparticles, combines particle stability with bondability, and less undergoes ion migration. A composite particle including metallic copper with the remainder being cuprous oxide and inevitable impurities is used for bonding typically of metals. The composite particle structurally includes metallic copper dispersed inside the particle and has an average particle size of 1000 nm or less.

### TECHNICAL FIELD

The present invention relates to metal oxide particles for bonding, a sintering binder containing the metal oxide particles, a method for producing the metal oxide particles for bonding, and a method for bonding electronic components.

### BACKGROUND ART

Metal nanoparticles (such as ones having a particle size of 100 nm or less) have large surface areas as compared to the volumes thereof, offer high chemical activities, and can be sintered at significantly lower temperatures. The metal nanoparticles therefore receive attention as novel functional materials. For example, pastes containing such metal nanoparticles are expected as materials for use in bonding of electronic components with each other, and formation of circuit wiring (circuit interconnections) in electronic devices. In these uses, generally preferred are metal nanoparticles having thermal conductivity, electroconductivity, and heat resistance (oxidation resistance) at high levels. These uses therefore often employ nanoparticles of noble metals such as gold and silver, and, among them, frequently employ silver nanoparticles, which are relatively inexpensive.

Disadvantageously, however, silver tends to undergo an ionic migration, and this often causes a short circuit. From the viewpoint of restraining the ionic migration, copper nanoparticles are effectively used. In addition, copper has a thermal conductivity (400 W/m·K) approximately equivalent to that of silver (430 W/m·K) and is significantly advantageous in cost as compared with silver.

As an exemplary method for producing the copper nanoparticles, Non-Patent Literature 1 reports a method using cetyltrimethylammonium bromide (CTAB) as a dispersant to give copper nanoparticles having a particle size of 100 nm or less. This method, however, requires cleaning of the copper nanoparticles before a sintering heat treatment so as to remove excessive CTAB.

Disadvantageously, however, the cleaning of the copper nanoparticles causes metal copper to be oxidized into cuprous oxide. Such cuprous oxide particles are generally reduced and sintered at 600° C. in hydrogen, and, once being in this state, hardly undergo sintering and bonding at low temperatures of 400° C. or lower.

In contrast, there are disclosed techniques for eliminating or minimizing oxidation of copper nanoparticles. The techniques typically include a technique of coating copper nanoparticles with a silicone oil upon preparation of the nanoparticles (typically see Patent Literature 1 and Patent Literature 2); a technique of adding an additive to a copper fine powder after its preparation to restrain the oxidation of copper (typically see Patent Literature 3); and a technique of mixing copper nanoparticles with a resin so as to adjust dispersibility and viscosity of the copper nanoparticles and restrain the oxidation (typically see Non-Patent Literature 2).

### PRIOR ART DOCUMENTS

### Patent Literatures

Patent Literature 1: Japanese Patent Application Laid-Open No. 2005-60779

Patent Literature 2: Japanese Patent Application Laid-Open No. 2005-60778

Patent Literature 3: Japanese Patent Application Laid-Open No. 2007-258123

### Non-Patent Literatures

Non-Patent Literature 1: Szu-Han Wu and Dong-Hwang Chen, Journal of Colloid and Interface Science 273 (2004) pp. 165-169.

Non-Patent Literature 2: 14th Symposium on “Microjoining and Assembly Technology in Electronics” (2008) p. 191-194.

### SUMMARY OF INVENTION

### Technical Problem

The copper nanoparticles disclosed in Patent Literature 1 and Patent Literature 2 are considered to be superior in oxidation resistance. However, the copper nanoparticles often causes the silicone oil to remain as a residue in a bonding site upon the sintering heat treatment when the copper nanoparticles are applied to bonding in a small space such as bonding of electronic components with each other, and this may lower the bonding strength and/or thermal conductivity. Also, in the technique disclosed in Non-Patent Literature 2, the resin tends to remain as a residue upon the sintering heat treatment, and this may adversely affect sinterability.

In the technique disclosed in Patent Literature 3 for coating particles with the additive, an antioxidant is adsorbed on the prepared copper fine particles typically using a ball mill. According to this technique, however, it may be difficult to uniformly coat nanoparticles having a particle size of 100 nm or less with the additive and to restrain the oxidation of the nanoparticles.

The present invention has been made under these circumstances and has an object to solve problems of conventional techniques and to provide a sintering binder mainly including nanoparticles, where the sintering binder includes cuprous oxide nanoparticles, in which the particles combine stability and bondability and can resist the ionic migration. The present invention has another object to provide a method for producing the sintering binder; and a method for bonding using the sintering binder.

### Solution to Problem

The present invention employs composite particles for bonding typically of metals, where the composite particles include metallic copper, with the remainder being cuprous oxide and inevitable impurities. The composite particles have a structure in which the metallic copper is dispersed inside the particles. The composite particles have an average particle size of 1000 nm or less.

### Advantageous Effects of Invention

The present invention can provide a sintering binder including copper-based particles, a method for producing the sintering binder, and a method for bonding using the sintering binder. The sintering binder mainly includes copper-cuprous oxide composite nanoparticles which combine stability and bondability and which less undergo the ionic migration.

### BRIEF DESCRIPTION OF DRAWINGS

FIG. 1 is a flow chart illustrating a method for synthesizing copper-cuprous oxide composite nanoparticles according to an embodiment of the present invention;

FIG. 2 is a flow chart illustrating a preferred embodiment of the synthesizing method illustrated in FIG. 1;

FIG. 3 is a schematic diagram conceptually illustrating a structure of a copper-cuprous oxide composite nanoparticle according to the present invention;

FIG. 4 is a graph illustrating XRD measurement results of synthesized composite nanoparticles;

FIG. 5 is a graph illustrating how a bonding strength varies depending on an average particle size of particles of Samples (Examples) 1 to 3 and of Comparative Samples 1 and 2;

FIG. 6A is a plane view of an insulated semiconductor device to which the present invention is applied;

FIG. 6B is a cross-sectional view taken along the line A-A in FIG. 6A;

FIG. 7 is a schematic perspective view of a principal part of the insulated semiconductor device illustrated in FIG. 6A; and

FIG. 8 is a schematic enlarged cross-sectional view of a portion where the semiconductor element of FIG. 6A is disposed.

### DESCRIPTION OF EMBODIMENTS

The present invention generally relates to sintering binders for use in bonding (joining) of electronic components with each other and for the formation of circuit wiring (circuit interconnections). Specifically, the present invention relates to a highly thermally conductive sintering binder which mainly includes cuprous oxide particles; a method for producing the sintering binder; and a method for bonding using the sintering binder. In this description, components such as semiconductor elements, integrated circuits, and circuit boards are generically referred to as “electronic components”. Non-limiting examples of the semiconductor elements include diodes and transistors. The “integrated circuits” include not only integrated circuits (ICs), but also large-scale integrated circuits (LSIs) and any other integrated circuits.

As described above, the sintering binder according to the present invention includes composite particles having an average particle size (average particle diameter) of 1000 nm or less, where the composite particles are each a particle including cuprous oxide as a principal component, and metallic copper particles dispersed inside the cuprous oxide particle. The composite particles preferably have an average particle size of 500 nm or less.

Improvements and modifications as follows may be made in the sintering binder according to the present invention.

(1) A solvent for use in the synthesis of the composite particles (copper-cuprous oxide composite nanoparticles) may be water alone or in combination with an alcoholic solvent as a mixed solvent.

(2) The sintering binder preferably contains the copper-cuprous oxide composite nanoparticles in a content of 90 mass percent or more.

(3) A method for producing the sintering binder may include the steps in the sequence set forth: dissolving a copper compound in the solvent described in (1) to form a solution containing copper ions; and combining the solution with a sodium borohydride solution (NaBH₄ solution) while allowing an inert gas to pass through the former solution, to form copper-cuprous oxide composite nanoparticles.

(4) In the method for producing the sintering binder, the copper compound may include at least one selected from copper nitrate hydrate, copper oxides, and copper carboxylates.

(5) A method for bonding electronic components with each other preferably includes the steps in the sequence set forth: applying the sintering binder to a bonding site; and performing a sintering heat treatment at 100° C. to 500° C. in a reducing atmosphere.

(6) In the method for bonding electronic components with each other, the reducing atmosphere is preferably selected from hydrogen, formic acid, and ethanol atmospheres.

(7) In the method for bonding electronic components with each other, the electronic components are preferably a chip and a circuit board to constitute a semiconductor device, and the sintering heat treatment is preferably performed while a pressure is applied in such a direction as to bond the chip and the circuit board with each other.

The composite particles are composite particles each including metallic copper, with the remainder being cuprous oxide and inevitable impurities, in which structure the metallic copper is dispersed inside the composite particles. The inevitable impurities are substances which are contained in the solution for the synthesis of the composite particles and are entrapped in the composite particles. Possible examples of the substances include boron, sodium, and nitrates. Accordingly, the composite particles can be said to approximately mainly include cuprous oxide.

Some embodiments of the present invention will be illustrated below, on the basis of the production procedure of the sintering binder with reference to the attached drawings. It should be noted, however, that the embodiments described herein are never intended to limit the scope of the present invention; and that various combinations and improvements may be made as appropriate within ranges not deviating from the spirit and scope of the present invention.

Sintering Binder Production Method

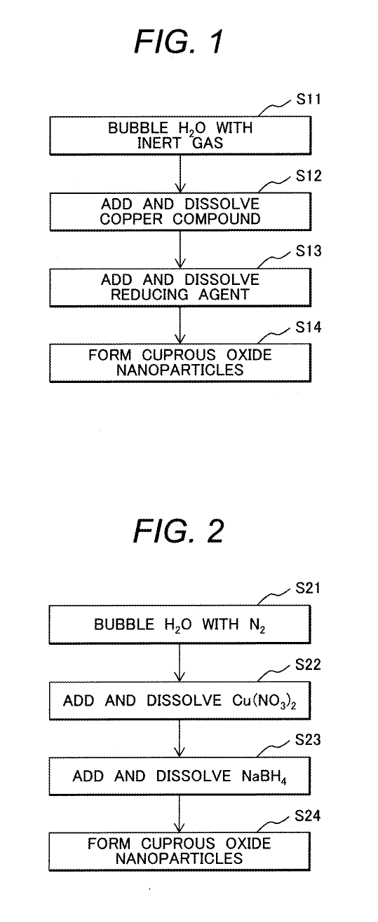

FIG. 1 is a flow chart illustrating how to synthesize copper-cuprous oxide composite nanoparticles, which are an essential component of the sintering binder according to the present invention.

In this figure, the copper-cuprous oxide composite nanoparticles are prepared in the following procedure. The composite nanoparticles are prepared using a reaction in an aqueous solution.

Initially, a solvent for synthesizing the copper-cuprous oxide composite nanoparticles is prepared by bubbling stirred distilled water with an inert gas (S11). This bubbling is hereinafter also referred to as “inert gas bubbling”. The inert gas bubbling is preferably performed for 30 minutes or longer. The inert gas bubbling is performed so as to remove dissolved oxygen from the solvent and to eliminate or minimize the formation of impurities other than copper-cuprous oxide composite particles upon synthesis. The inert gas may be any inert gas that restrains the reaction of copper ions in the solution with other components than the copper-cuprous oxide composite particles. Non-limiting examples of such inert gas include nitrogen gas, argon gas, and helium gas. The inert gas bubbling is desirably continued until the completion of synthesis of the copper-cuprous oxide composite particles. The flow rate of the inert gas in bubbling is not especially limited, but is preferably in the range of 1 mL/min to 1000 mL/min per 1000 mL of water.

Next, while the solvent is controlled in temperature at 5° C. to 90° C. and stirred, a copper compound powder, which acts as a raw material, is dissolved in the solvent to form copper ions (S12). The raw material copper compound is preferably selected from compounds that can minimize residues derived from anions upon dissolution, and are preferably selected typically from copper nitrate trihydrate, copper chlorides, copper hydroxides, and copper carboxylates such as copper acetates. Among them, copper nitrate trihydrate is particularly preferred because amounts of impurities generated upon cuprous oxide synthesis are less.

The copper compound solution has such a concentration of preferably 0.001 to 1 mol/L. Particularly preferable copper concentration is 0.010 mol/L. If the copper compound solution has a concentration of less than 0.001 mol/L, it is excessively dilute and may disadvantageously lower the yield of the copper-cuprous oxide composite nanoparticles. In contrast, if the copper compound solution has a concentration of greater than 1 mol/L, it may disadvantageously cause the copper-cuprous oxide composite nanoparticles to aggregate excessively.

The solvent temperature is set in the range of 5° C. to 90° C. for reasons as follows. This synthesis method uses a solvent mainly containing water. Thus, the synthesis method may disadvantageously fail to give nanoparticles which are stable in size and shape if the synthesis method is performed at a solvent temperature (reaction temperature) of higher than 90° C. In contrast, the method may disadvantageously less satisfactorily give the target copper-cuprous oxide particles and may cause a lower yield, if the method is performed at a solvent temperature (reaction temperature) of lower than 5° C.

Next, a reducing agent is added (S13), and copper-cuprous oxide composite nanoparticles are formed thereby (S14). The reducing substance (reducing agent) to be added is not especially limited, but may be advantageously selected typically from sodium borohydride (NaBH₄), hydrazine, and ascorbic acid. Among them, NaBH₄ is particularly referred. This is because NaBH₄ has a low impurity content and less forms by-products and impurities upon synthesis.

The amount of the reducing agent is preferably set so that the mole ratio (NaBH₄/[Cu²⁺]) of NaBH₄ to the copper ions [Cu²⁺] be 1.0 or more and less than 3.0. This is because the reducing agent may be present at a mole ratio excessively exceeding the stoichiometric ratio and may disadvantageously allow impurities to remain if the reducing agent is used in a mole ratio “NaBH₄/[Cu²⁺]” of 3.0 or more. In contrast, the reducing agent may offer insufficient reducing power if the reducing agent is used in a mole ratio “NaBH₄/[Cu²⁺]” of less than 1.0.

As described above, in the synthesis method, the solvent mainly including water is used. Mixing further a polar organic solvent to the solvent enables to control the reaction rate and the primary particle size. The polar organic solvent is preferably selected from alcohols such as ethanol, methanol, isopropyl alcohol, 2-ethylhexyl alcohol, ethylene glycol, triethylene glycol, and ethylene glycol monobutyl ether; aldehydes such as acetaldehyde; and polyols such as glycols. The polar organic solvent may be mixed with water in any mixing ratio. In addition to the polar organic solvent, a nonpolar organic solvent may also be added to the solvent. Non-limiting examples of the nonpolar organic solvent include acetone and other ketones, tetrahydrofuran, N,N-dimethylformamide, toluene, hexane, cyclohexane, xylenes, and benzene.

The synthesis time is not especially limited, but is preferably in the range of 1 minute to 336 hours (14 days). The synthesis may cause a lower yield because the synthesis reaction is not completed if the synthesis is performed for a time of 1 minute or shorter. In contrast, synthesis after a lapse of 336 hours may be useless, because the synthesis reaction is completed within at longest 336 hours.

The nanoparticles synthesized in the above manner may be used as intact as the sintering binder, but is preferably subjected to a centrifugal cleaning 1 to 10 times after the synthesis, because unreacted materials, by-products, and anions may remain after the synthesis. The centrifugal cleaning removes the unreacted materials, the by-products, and the anions remained after the synthesis. The cleaning liquid for use herein is preferably selected from water and the above-mentioned polar organic solvents.

The copper-cuprous oxide composite nanoparticles resulting from the centrifugal cleaning are preferably dried and then dispersed in an appropriate liquid (dispersion medium) to give a pasty sintering binder. In this process, the sintering binder preferably contains the copper-cuprous oxide composite nanoparticles in a content of 90 mass percent or more, from the viewpoint of higher bonding strength. The dispersion medium for use herein is preferably selected from water and the above-mentioned polar organic solvents (such as alcohols, aldehydes, and polyols). The dispersion medium may further contain any of the nonpolar organic solvents, in combination with the polar organic solvent or solvents.

FIG. 2 illustrates a preferred embodiment of the method for synthesizing copper-cuprous oxide composite nanoparticles.

According to the embodiment illustrated in this figure, distilled water is bubbled with nitrogen as the inert gas (S21).

Next, copper nitrate trihydrate as the copper compound is added and dissolved (S22). Next, NaBH₄ as the reducing agent is added and dissolved (S23). This forms copper-cuprous oxide composite nanoparticles (S24).

The sintering binder may further include a dispersant so as to allow the cuprous oxide nanoparticles to disperse more satisfactorily in the sintering binder. The dispersant for use herein is preferably one that less affects the sintering bonding (less leaves residues). Non-limiting examples of such dispersant include sodium dodecyl sulfate, cetyltrimethylammonium chloride (CTAC), citric acid, ethylenediaminetetraacetic acid, sodium bis(2-ethylhexyl)sulfonate (AOT), cetyltrimethylammonium bromide (CTAB), polyvinylpyrrolidones, poly(acrylic acid)s, poly(vinyl alcohol)s, and polyethylene glycols. The dispersant may be mixed approximately in such an amount as to allow the nanoparticles to disperse more satisfactorily and is preferably mixed in a proportion of 30 parts by mass or less per 100 parts by mass of the copper-cuprous oxide composite nanoparticles. The dispersant tends to remain as residues in the bonding layer and to cause lower bonding strength if the dispersant is added in a proportion greater than the range.

Properties of Copper-Cuprous Oxide Composite Nanoparticles

The copper-cuprous oxide composite nanoparticles may have an average particle size of preferably 2 to 500 nm, and more preferably 10 to 200 nm. This is because the copper-cuprous oxide composite nanoparticles may have excessively high chemical activities and oxidize even the copper component in the cuprous oxide particles, if having the average particle size of less than 2 nm. In contrast, the copper-cuprous oxide composite nanoparticles may include larger amounts of aggregated components to cause lower bonding strength, if having the average particle size of greater than 500 nm.

One of the most striking features of the metal oxide particles according to the present invention for bonding is that copper fine particles, as a component, are contained inside each of cuprous oxide particles. The cuprous oxide particles have a size of preferably 2 nm to 500 nm. This is because the cuprous oxide particles may cause larger amounts of porous regions in the bonding layer, if having a size greater than 500 nm, and this may impede the formation of a homogeneous particle layer and may cause lower bonding strength. The contained copper fine particles should have a size smaller as compared with the matrix cuprous oxide particles and, from this viewpoint, preferably have a size in the range of 0.1 to 100 nm. This is because the copper fine particles may have an abruptly increased specific surface area of copper to have better catalysis and to thereby promote the reduction of cuprous oxide, when having a size of 100 nm or less.

The composite particles may contain the copper fine particles in an amount of preferably 20% or less of the total amount of the composite particles. If the composite particles contain the copper fine particles in an amount greater than the range, the composite particles may cause copper ions to be reduced to zerovalent copper in a larger amount during the synthesis process to thereby form composite particles having larger particle sizes. If the composite particles have larger particle sizes as above, the composite particles may cause larger amounts of porous regions in the bonding layer, and this may impede the formation of a homogeneous particle layer and may cause lower bonding strength.

The components (chemical composition) of the copper-cuprous oxide composite particles may be determined (identified) by X-ray diffractometry (XRD). The copper and cuprous oxide contents may also be calculated from a weight loss determined by thermogravimetry (TGA) in hydrogen. The particle size (particle diameter) may be calculated typically using an electron microscope or by a particle size distribution measurement. The properties of the copper-cuprous oxide composite nanoparticles may be observed or determined typically using an electron microscope by energy dispersive X-ray spectrometry (EDX) or by electron energy-loss spectroscopy (EELS).

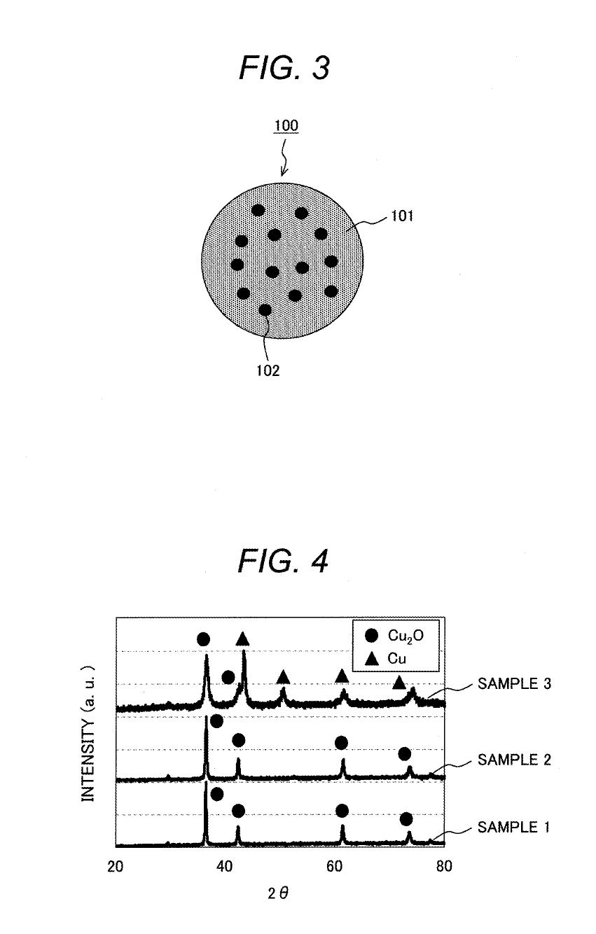

FIG. 3 is a schematic diagram illustrating a structure of a copper-cuprous oxide composite nanoparticle.

As illustrated in FIG. 3, the copper-cuprous oxide composite nanoparticle 100 is considered to have such a structure that copper fine particles 102 are dispersed inside a cuprous oxide nanoparticle 101. In this structure, the copper fine particles 102 have not yet been observed even with a regular transmission electron microscope (TEM). However, the structure is considered to be proper on the basis of measurement results (FIG. 4) obtained by an XRD apparatus as mentioned later. The inventors of the present invention have found the structure.

Sintering Heat Treatment

The sintering heat treatment on the sintering binder according to the present invention is preferably performed as a heat treatment at a temperature of 100° C. to 500° C. in a reducing atmosphere. The reducing atmosphere is not particularly limited, but is preferably selected typically from hydrogen atmosphere, formic acid atmosphere, and ethanol atmosphere.

The present invention will be illustrated in further detail with reference to several examples below. It should be noted, however, that these are by no means intended to limit the scope of the present invention.

### EXAMPLE 1

Preparation of Copper Oxide Nanoparticles

There were used Cu(NO₃)₂.3H₂O powder (supplied by Kanto Chemical Co., Inc.) as a material copper compound; water as a solvent; and NaBH₄ (supplied by Kanto Chemical Co., Inc., 92.0%) as a precipitating agent for copper-cuprous oxide nanoparticles. Distilled water was bubbled with nitrogen for 30 minutes in a 1000-mL capacity beaker, and 1000 mL of the distilled water after bubbling were combined with the Cu(NO₃)₂.3H₂O powder so as to give a copper ion concentration of 0.01 mol/L, and the powder was uniformly dissolved on a water bath at 40° C. Thereafter 0.2 to 0.6 mol/mL NaBH₄ aqueous solution (50 mL) was added dropwise, and synthetically yielded copper-cuprous oxide nanoparticles.

After stirring at room temperature for 24 hours, the synthesized copper-cuprous oxide nanoparticles were subjected to centrifugal separation and cleaning (washing) each three times using a centrifugal cleaner Suprema 21 (supplied by Tomy Seiko Co., Ltd.). The resulting copper-cuprous oxide nanoparticles were retrieved, dried, and yielded 0.0850 g of copper-cuprous oxide composite particles (Samples 1 to 3).

Examination of Copper-Cuprous Oxide Composite Nanoparticles Properties

The prepared copper-cuprous oxide composite particles (Samples 1 to 3) were subjected to particle size measurements using a particles size analyzer (Zetasizer Nano ZS90, supplied by Malvern Instruments Ltd). Measurement specimens used herein were prepared by diluting solutions after the nanoparticle preparation. Components constituting the particles were measured (identified) using an X-ray diffractometer (RU200B, supplied by Rigaku Corporation) at a scanning rate of 2 deg/min. Contents (chemical compositions) of copper and copper oxide particles in the composite particles, and reduction temperatures of the composite particles were calculated using a simultaneous thermogravimetric analyzer (Model TGA/SDTA 851, supplied by Mettler-Toledo International Inc.) in hydrogen.

Comparative Sample 1 was cuprous oxide particles supplied by Wako Pure Chemical Industries, Ltd.; and Comparative Sample 2 was copper nanoparticles (Cu nanoparticles) supplied by Aldrich. Comparative Sample 3 was prepared by mixing cuprous oxide particles (supplied by Wako Pure Chemical Industries, Ltd.) with copper nanoparticles (supplied by Aldrich) in proportions of 50 mass percent each.

FIG. 4 depicts XRD measurement results of Samples 1 to 3, demonstrating that cuprous oxide was detected from each of particles according to Samples 1, 2, and 3. In addition, clear copper peaks were observed in Sample 3. Clear copper peaks were not observed in the XRD measurement results of Samples 1 and 2. However, a large amount of cuprous oxide and a trace amount of copper were detected in XPS measurement, which was separately performed using JPS-9010TR (supplied by JEOL Ltd.).

The results demonstrated that Samples 1, 2 and 3 are copper-cuprous oxide nanoparticles (composite particles) schematically illustrated in FIG. 3. In addition, the proportions of copper and cuprous oxide were calculated on the basis of results of measurements using a simultaneous thermogravimetric analyzer in hydrogen.

These demonstrated that Samples 1 to 3 (particles synthesized at varying NaBH₄ concentrations of 0.01 M to 0.02 M) are composite particles of copper and cuprous oxide and have lower reduction temperatures as compared with the cuprous oxide alone according to Comparative Sample 1 by about 250° C. to about 300° C. This is probably because copper fine particles are present inside a cuprous oxide particle and act as a catalyst to cause the reduction temperatures to be lower as compared with a bulk particle.

Comparative Sample 3 is a sample prepared by blending the cuprous oxide particles (supplied by Wako Pure Chemical Industries, Ltd.) with the copper nanoparticles (supplied by Aldrich) in proportions of 50 mass percent each. In Comparative Sample 3, the cuprous oxide particles have a lower reduction temperature by about 70° C. as a result of the catalysis of the copper nanoparticles, but the lowering of the reduction temperature was not so effective as compared with Samples 1 to 3.

The results demonstrated that it is of importance that copper fine particles are contained (present) inside cuprous oxide particles. This is probably because copper particles, as being present more finely in cuprous oxide, offer better catalysis.

Table 1 collectively presents synthesis conditions and properties of the particles of Samples 1 to 3 and Comparative Samples 1 to 3.

TABLE 1
Properties of binder in Samples 1 to 3

| | | | Sample | Sample | Sample | Comparative | Comparative | Comparative |
|---|---|---|---|---|---|---|---|---|
| | | | 1 | 2 | 3 | Sample 1 | Sample 2 | Sample 3 |
| Synthesis | NaBH₄ concentration | | 0.01 | 0.015 | 0.02 | — | — | — |
| conditions | (M) | | | | | | | |
| Particle | Average particle size | | 334 | 656 | 491 | 5000 | 100 | 5000 |
| properties | (nm) | | | | | | | |
| | Component | Copper | 4 | 3 | 22 | — | 99 | 50 |
| | | (mass | | | | | | |
| | | percent) | | | | | | |
| | | Cuprous | 96 | 97 | 78 | 99 | — | 50 |
| | | oxide | | | | | | |
| | | (mass | | | | | | |
| | | percent) | | | | | | |

| | | | | | | |
|---|---|---|---|---|---|---|
| Reduction temperature | 330 | 322 | 273 | 572 | — | 500 |
| (° C.) | | | | | | |
| Bonding strength (MPa) | 27.9 | 18.2 | 8.9 | 0 | 16 | 0 |

### EXAMPLE 2

Bonding Strength Test of Copper-Cuprous Oxide Composite Nanoparticles

Bonding strength tests were performed while simulating bonding of electronic components with each other. The tests were performed each in the following manner. Copper test specimens used in the measurement were a lower test specimen having a diameter of 10 mm and a thickness of 5 mm; and an upper test specimen having a diameter of 5 mm and a thickness of 2 mm. The prepared sintering binder was applied onto the lower test specimen, and the upper test specimen was placed on the applied sintering binder, followed by a sintering heat treatment at a temperature of 400° C. in hydrogen for 5 minutes. This process was performed while a load in terms of compacting pressure of 1.2 MPa was applied. A shear stress was loaded on the test specimens after bonding at a rate of shear of 30 mm/min, and a peak load at rupture was measured using a shear tester (Bond Tester SS-100KP, supplied by Seishin Trading Co., Ltd., maximum load: 100 kg). The peak load was divided by the bonding surface area to determine a bonding strength.

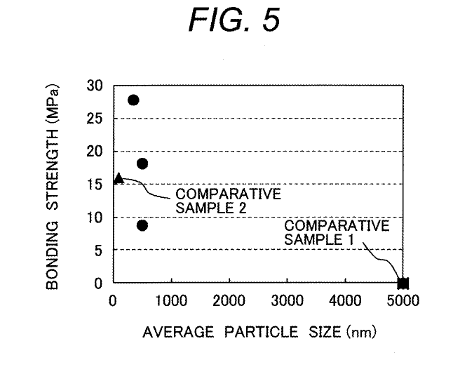

The determined bonding strengths of Samples 1 to 3 are also presented in Table 1. FIG. 5 illustrates how the bonding strength varies depending on the average particle size. In FIG. 5, data of Samples 1 to 3 are indicated with filled circles; and data of Comparative Samples 1 and 2 were indicated respectively with a filled square and a filled triangle.

Data as illustrated in FIG. 5 demonstrated that the copper-cuprous oxide particles according to the present invention have a higher bonding strength with a decreasing average particle size. This is probably because the copper-cuprous oxide particles, when having a smaller average particle size, allows particles after reduction to have smaller sizes and to have better sinterability, and this allows the bonding layer to more readily have a higher density (better compactibility) and to offer higher bonding strength.

The data also demonstrated that Samples 1 and 2 offer higher bonding strengths as compared with Comparative Samples 1 and 2. Samples 1 and 2 have higher bonding strengths as compared with Comparative Sample 1, because the cuprous oxide has a lower reduction temperature, and this allows copper particles, which are formed as a result of reduction from the copper oxide particles, to more readily undergo sintering. Samples 1 and 2 have higher bonding strengths as compared with the copper nanoparticles according to Comparative Sample 2, probably because as follows. The copper nanoparticles are surrounded by (coated with) an organic material coating so as to stabilize the particles. However, the copper-cuprous oxide particles according to the present invention do not bear such a coating, undergo sintering more satisfactorily, and consequently offer high bonding strengths.

### EXAMPLE 3

Application to Semiconductor Devices

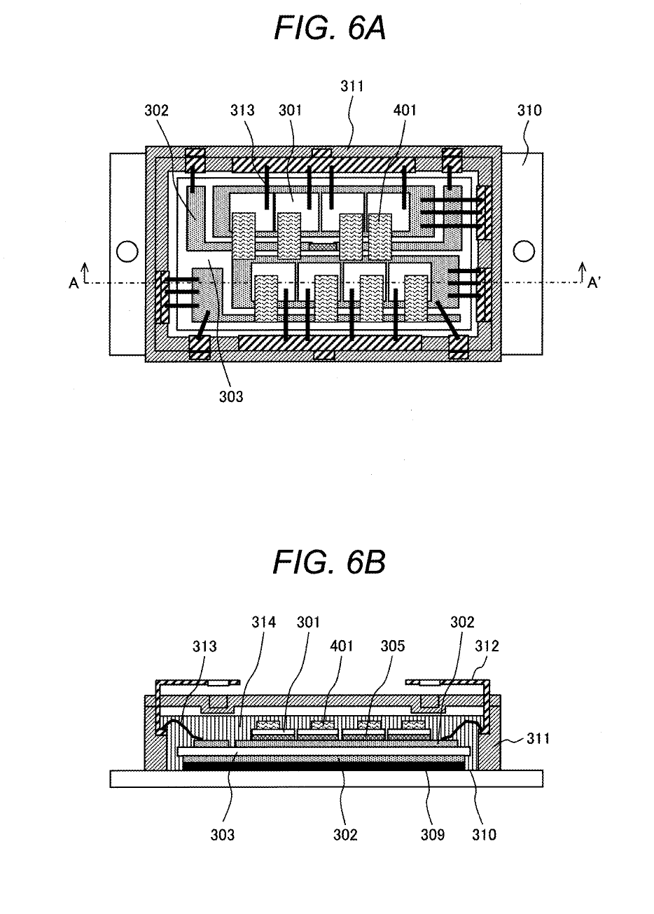

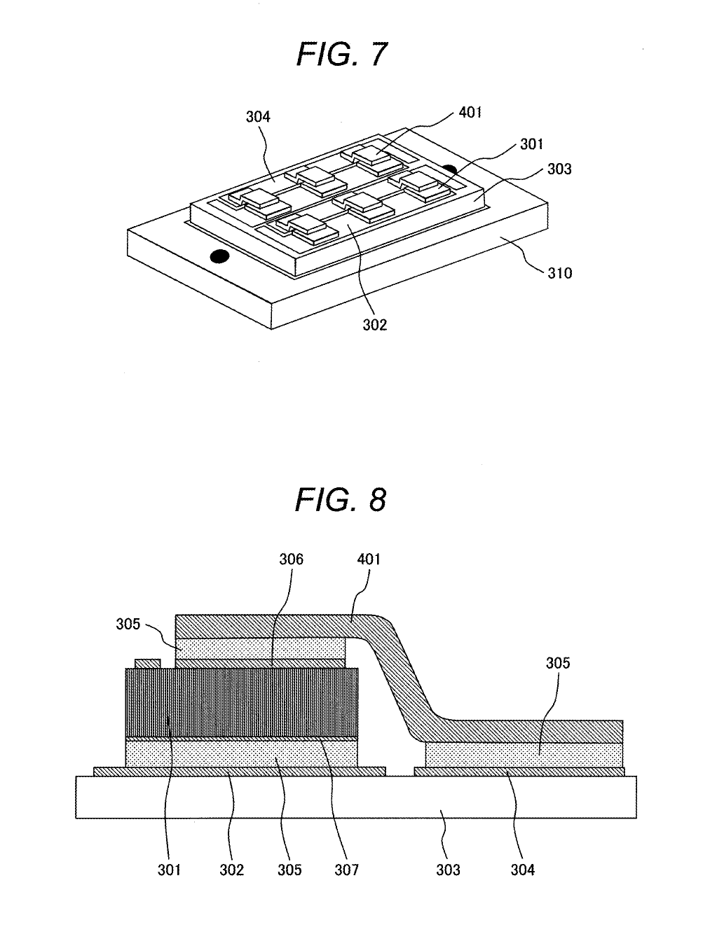

FIG. 6A is a plan view of an insulated semiconductor device to which the present invention is applied. FIG. 6B is a cross-sectional view taken along the line A-A in FIG. 6A. FIG. 7 is a perspective view of the principal part of the device in FIG. 6A. FIG. 8 is a schematic enlarged cross-sectional view of a portion where the semiconductor element illustrated in FIG. 6A is placed. The semiconductor device will be illustrated below with reference to FIGS. 6A, 6B, 7, and 8.

A circuit board including a ceramic insulated substrate 303 and an interconnection layer 302 is bonded through a solder layer 309 to a supporting substrate 310. The interconnection layer 302 includes copper interconnections coated with nickel. A collector electrode 307 of the semiconductor element 301 is bonded to the interconnection layer 302 on the ceramic insulated substrate 303 through a bonding layer 305 formed from the copper-cuprous oxide composite particles according to the present invention. The bonding layer 305 becomes a pure copper layer after bonding.

In addition, an emitter electrode 306 of the semiconductor element 301 is bonded to a connecting terminal 401 through a bonding layer 305. This bonding layer 305 is formed from a binder including the particles prepared in Example 1 at a NaBH₄ concentration of 0.01 M. This bonding layer 305 also becomes a pure copper layer after bonding.

The connecting terminal 401 is bonded to the interconnection layer 304 on the ceramic insulated substrate 303 through a bonding layer 305 formed from the sintering binder according to the present invention, where the bonding layer 305 becomes a pure copper layer after bonding. The bonding layers 305 each have a thickness of 80 μm. A nickel coating is disposed on the collector electrode 307 and on the emitter electrode 306. The connecting terminal 401 includes Cu or a Cu alloy.

FIGS. 6A and 6B also depict a cabinet 311, an external terminal 312, a bonding wire 313, and an encapsulant 314.

The bonding layers 305 may be formed typically by preparing a sintering binder containing 90 mass percent of the copper-cuprous oxide composite particles according to the present invention and 10 mass percent of water; applying the sintering binder to a bonding surface of a member to be bonded; drying the applied sintering binder at 80° C. for 1 hour; and performing a sintering heat treatment at 350° C. in hydrogen for 1 minute while a pressure of 1.0 MPa is applied. The bonding may be performed with the application of an ultrasonic vibration.

The bonding layers 305 may be formed individually or simultaneously.

### REFERENCE SIGNS LIST

100 . . . copper-cuprous oxide composite nanoparticle,

101 . . . cuprous oxide nanoparticle,

102 . . . copper fine particles,

301 . . . semiconductor element,

302, 304 . . . interconnection layer,

303 . . . ceramic insulated substrate,

305 . . . bonding layer,

306 . . . emitter electrode,

307 . . . collector electrode,

309 . . . solder layer,

310 . . . supporting substrate,

311 . . . cabinet,

312 . . . external terminal,

313 . . . bonding wire,

314 . . . encapsulant,

401 . . . connecting terminal.

1. A sintering binder comprising:
composite particles; and
a dispersion medium,
the composite particle including:
metallic copper;
cuprous oxide; and
inevitable impurities,
the composite particles including the cuprous oxide in a content of 78 mass percent or more of the total amount of the composite particles,
the composite particles having a structure in which the metallic copper is dispersed inside each of the composite particles,
the composite particles having an average particle size of 1000 nm or less,
the cuprous oxide having a size of 2 nm to 500 nm,
the metallic copper having a size of 0.1 nm to 100 nm,
the sintering binder including the composite particles in a content of 90 mass percent or more of the total amount of the sintering binder.

2. (canceled)

3. (canceled)

4. A method for producing a sintering binder, the sintering binder including:
composite particles; and
a dispersion medium,
the composite particles including:
metallic copper;
cuprous oxide; and
inevitable impurities,
the composite particles including the cuprous oxide in a content of 78 mass percent or more of the total amount of the composite particles,
the composite particles having a structure in which the metallic copper is dispersed inside each of the composite particles,
the composite particles having an average particle size of 1000 nm or less,
the cuprous oxide having a size of 2 nm to 500 nm,
the metallic copper having a size of 0.1 nm to 100 nm,
the sintering binder including the composite particles in a content of 90 mass percent or more,
the method comprising the step of
mixing a reducing agent with an aqueous solution of a copper compound containing divalent or higher copper to form the composite particles by precipitating.

5. The method for producing the sintering binder according to claim 4,
wherein the copper compound includes at least one compound selected from the group consisting of:
copper nitrate trihydrate;
copper chlorides;
copper hydroxides; and
copper acetates.

6. The method for producing the sintering binder according to claim 4,
wherein the reducing agent includes NaBH₄.

7. The method for producing the sintering binder according to claim 4,
wherein the dispersion medium includes at least one selected from the group consisting of:
water;
alcohols;
aldehydes; and
polyols.

8. A method for bonding the electronic components, the method being for bonding two electronic components with each other,
the method comprising the steps in the sequence set forth:
a) applying the sintering binder according to claim 1 to at least one of bonding surfaces of the two electronic components, and arranging the applied sintering binder between the bonding surfaces of the two electronic components; and
b) subjecting the electronic components to a sintering heat treatment at 100° C. to 500° C. in a reducing atmosphere.

9. The method for bonding the electronic components according to claim 8,
wherein the reducing atmosphere includes at least one selected from the group consisting of:
hydrogen;
formic acid; and
ethanol.

10. The method for bonding the electronic components according to claim 8,
wherein the sintering heat treatment is performed while a pressure is applied so as to allow the bonding surfaces of the two electronic components to be in intimate contact with each other.
